(19) United States
(12) Patent Application Publication
(10) Pub. No.: US 2007/0054502 A1
(43) Pub. Date: Mar. 8, 2007

(54) Nanodot memory and fabrication method thereof

(76) Inventors: Kwang Soo Seol, Suwon (KR); Kyung Sang Cho, Gwancheon (KR); Byung Ki Kim, Gunpo (KR); Eun Hye Lee, Seoul (KR); Jae Young Choi, Suwon (KR)

Correspondence Address: HARNESS, DICKEY & PIERCE, P.L.C., P.O. BOX 8910, RESTON, VA, 20195, US

(21) Appl. No.: 11/514,200

(22) Filed: Sep. 1, 2006

(30) Foreign Application Priority Data
Sep. 2, 2005 (KR) 10-2005-0081790

(51) Int. Cl. H01L 21/31

(52) U.S. Cl. 438/782

(57) ABSTRACT

A nanodot memory formed by applying a nanodot colloid solution on a semiconductor substrate to more uniformly arranging nanodot particles with a size of several nanometers on the semiconductor substrate and a fabrication method thereof are provided. In the nanodot memory fabrication method, a first insulating film may be formed on a surface of a substrate. A nanodot colloid solution may be applied on the first insulating film. A solvent in the nanodot colloid solution may be removed such that a nanodot particles layer remains exposed on the first insulating film. A second insulating film may be formed on a surface of the semiconductor substrate, on which the nanodot particles are exposed. The nanodot particles may be formed in a monolayer structure by adjusting a concentration of nanodot particles within the nanodot colloid solution.

### PRIORIY STATEMENT

This application claims the benefit of priority under 35 U.S.C. §119 from Korean Application No. 10-2005-0081790, filed on Sep. 2, 2005 in the Korean Intellectual Priority Office (KIPO), the contents of which are incorporated herein by reference in their entirety.

### BACKGROUND OF THE INVENTION

1. Field of the Invention

Example embodiments of the present invention relate to a nanodot memory and a fabrication method thereof. Other example embodiments of the present invention relate to a nanodot memory formed by applying a metal nanodot colloid solution on a semiconductor substrate to more uniformly arrange nanodot particles with a size of several nanometers on the semiconductor substrate.

2. Description of the Related Art

It is well-known in the art that a semiconductor structure wherein a floating gate capable of storing electric charges may be used as a non-volatile memory device. The use of such non-volatile memory devices rapidly increases as portable electronic equipment evolves. With the development of semiconductor technology, there is a continuous effort to reduce power consumption of such non-volatile memory devices by lowering an operating voltage thereof, while maintaining functionality and/or speed thereof.

The conventional art acknowledges a method wherein a tunnel oxide film under the floating gate may be reduced in thickness, and the floating gate may be replaced by a plurality of separate storage elements. A more highly integrated memory device may be implemented when nanodot particles are used as the plurality of separate storage elements.

The nanodot particles, which may have nanometer-scale size, may exhibit different optical, magnetic and/or electrical properties from nanodot particles in a bulk state. The optical, magnetic and electrical physical properties, which vary with particle size, may be more effective for fabricating an optical device having a desired quantum efficiency, a higher density magnetic recorder, a single-electron transistor and/or a memory device.

The conventional art also acknowledges a method for fabricating the nanodot using a nanodot colloid solution having nanodot particles. The nanodot colloid solution is a solution wherein nanodot particles with a size of several nanometers (nm) to several micrometers (μm) may be more uniformly dispersed in a solvent without (or minimal) agglomeration.

According to the conventional methods, a metal nanodot colloid solution having metal nanodot particles may be dropped (or deposited) onto a substrate by means of a dropper (or spuit) to form arrangement of nanodot particles.

It may be difficult to apply the colloid solution with more uniform thickness on a substrate having a large area. It may be difficult to more uniformly arrange nanodot particles over the entire substrate when the colloid solution is applied non-uniformly.

### SUMMARY OF THE INVENTION

Example embodiments of the present invention relate to a nanodot memory and a fabrication method thereof. Other example embodiments of the present invention relate to a nanodot memory formed by applying a metal nanodot colloid solution on a semiconductor substrate to more uniformly arrange nanodot particles with a size of several nanometers on the semiconductor substrate.

Other example embodiments provide a method for fabricating a nanodot memory, which may more easily form a nanodot particles layer in a monolayer structure using a nanodot colloid solution.

In yet further example embodiments, a method is provided for fabricating a nanodot memory wherein contamination in a device area may be reduced. In other example embodiments, contamination in a critical tunnel oxide portion of a device may be reduced.

A method for fabricating a nanodot memory in accordance with example embodiments may include forming a first insulating film on a surface of a substrate, applying a nanodot colloid solution on the first insulating film, removing (or evaporating) a solvent in the nanodot colloid solution such that a plurality of nanodot particles remains on the first insulating film, forming a second insulating film on a surface of the substrate on which the nanodot particles are exposed and/or forming an upper electrode on the second insulating film, wherein the nanodot particles are formed in a monolayer structure by adjusting a concentration of nanodot particles in the nanodot colloid solution.

In an example embodiment, the concentration of the nanodot particles in the nanodot colloid solution may be about 0.5 to 1.2 percent-by-weight (hereinafter referred to as “wt %”).

In an example embodiment, the nanodot colloid solution may include a metal selected from the group including nickel, cobalt, iron, platinum, silver, palladium and alloys thereof. The nanodot colloid solution may include a nonpolar solvent. The nonpolar solvent may be hexane or diphenylether. In an example embodiment, the metal nanodot colloid solution may include a dispersant. The dispersant may include at least one compound selected from the group including oleic acid, trioctylamine and trioctylphosphine.

In an example embodiment, the metal nanodot colloid solution may be applied by means of a spin coating method.

In an example embodiment, the first and second insulating films may be thin films. The first and second insulating films may be selected from the group including a silicone oxide thin film, a silicon oxynitride thin film, a silicon nitride thin film, a titanium oxide thin film, an aluminum oxide thin film or a hafnium oxide thin film and a laminate thin film thereof.

In an example embodiment, the second insulating film may be formed using a low-pressure chemical vapor deposition (LPCVD) process. The solvent in the nanodot colloid solution may be evaporated under a vacuum atmosphere.

After the nanodot particles are formed, the surface of the substrate may be treated with oxygen plasma. In other example embodiments, the substrate may be subjected to a heat treatment at a temperature of about 300° C. or above.

In accordance with example embodiments, there is provided a nanodot memory including a substrate formed of semiconductor material, a first insulating film formed on the substrate, a plurality of nanodot gates formed on the first insulating film from a nanodot colloid solution, a second insulating film formed on the first insulating film and the nanodot gates and/or an upper electrode formed on the second insulating film.

In an example embodiment, the nanodot gates may be a monolayer of nanodot particles. There may be a distance of 1 nm to 10 nm between the nanodot gates.

In an example embodiment, the nanodot gates may be formed of a metal selected from the group including nickel, cobalt, iron, platinum, silver, palladium and alloys thereof.

In an example embodiment, the nanodot gates may have a carbon atomic concentration of about 2% or less.

In an example embodiment, the first and second insulating films may be selected from the group including a silicone oxide thin film, a silicon oxynitride thin film, a silicon nitride thin film, a titanium oxide thin film, an aluminum oxide thin film or a hafnium oxide thin film, and a laminate thin film thereof.

### BRIEF DESCRIPTION OF THE DRAWINGS

Example embodiments of the present invention will be more clearly understood from the following detailed description taken in conjunction with the accompanying drawings. FIGS. 1-14 represent non-limiting, example embodiments of the present invention as described herein.

FIG. 1 is a flowchart illustrating a method for fabricating a nanodot memory according to example embodiments of the present invention;

FIGS. 2 to 4 are sectional views illustrating a nanodot memory formed according to example embodiments of the present invention;

FIG. 5 is a graph showing particle coverage as a function of nanodot particle concentration in a metal nanodot solution fabricating by a nanodot memory fabrication method according to example embodiments of the present invention;

FIG. 6 is a TEM photograph of an arrangement of nanodot particles formed using a metal nanodot colloid solution including approximately 1.0 wt % nickel nanodot particles according to example embodiments of the present invention;

FIG. 7 is a sectional TEM photograph of a structure having a silicon oxide film, a nickel nanodot, a silicon oxide film and an aluminum electrode sequentially formed on a silicon substrate according to example embodiments of the present invention;

FIGS. 8 to 10 are magnified photographs of FIG. 7;

FIG. 11 is a graph showing atomic concentration of carbon atoms implanted into a device that is treated with oxygen plasma as a function of sputter time according to example embodiments of the present invention;

FIG. 12 is a graph showing atomic concentration of carbon atoms implanted into a device that is not treated with oxygen plasma as a function of sputter time according to example embodiments of the present invention;

FIG. 13 is a graph showing capacitance as a function of voltage hysteresis characteristic of a capacitor having the structure of FIG. 7; and

FIG. 14 is a graph showing a flat band voltage characteristic as a function of maximum sweep voltage according to example embodiments of the present invention.

### DETAILED DESCRIPTION OF EXAMPLE EMBODIMENTS

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments of the invention. As used herein, the singular forms “a,” “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath,” “below,” “lower,” “above,” “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Also, the use of the words “compound,” “compounds,” or “compound(s),” refer to either a single compound or to a plurality of compounds. These words are used to denote one or more compounds but may also just indicate a single compound.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described.

Example embodiments of the present invention relate to a nanodot memory and a fabrication method thereof. Other example embodiments of the present invention relate to a nanodot memory formed by applying a metal nanodot colloid solution on a semiconductor substrate to more uniformly arrange nanodot particles with a size of several nanometers on the semiconductor substrate.

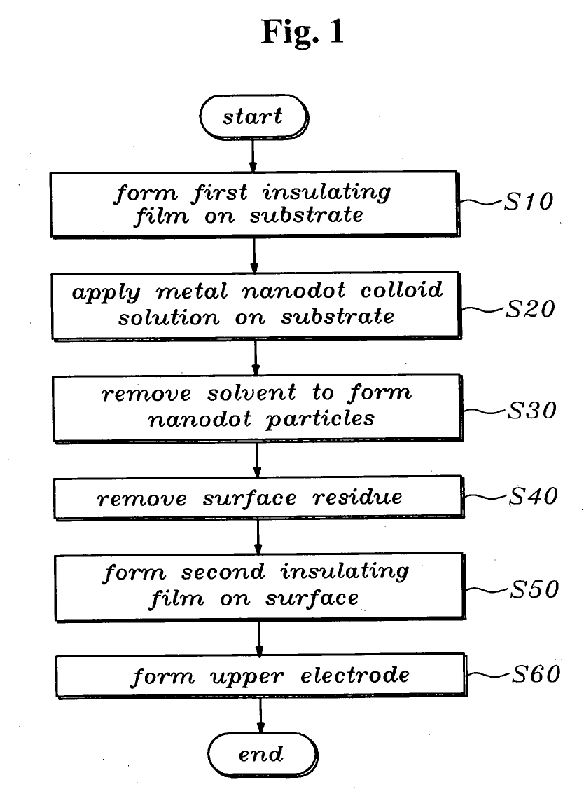

FIG. 1 is a flowchart illustrating a nanodot memory fabrication method in accordance with example embodiments of the present invention.

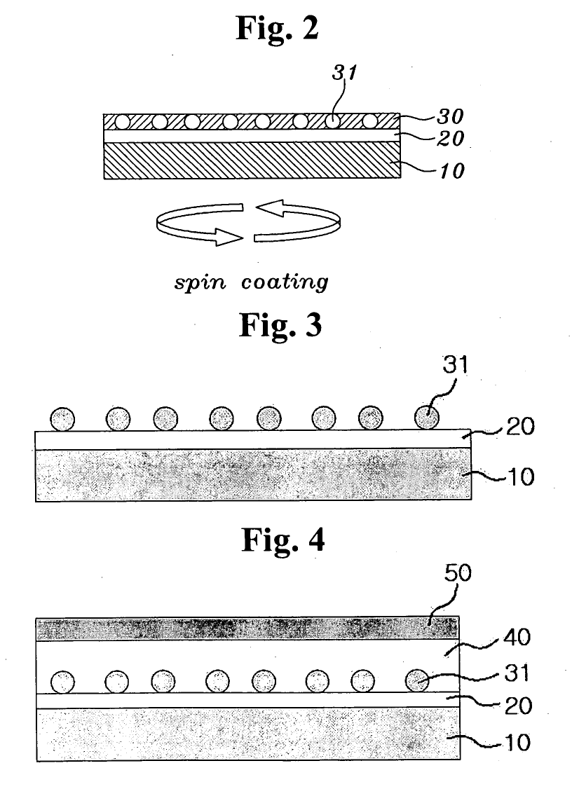

FIGS. 2 to 4 are diagrams illustrating sectional views of a nanodot memory fabricated according to example embodiments of the present invention.

Referring to FIGS. 1 to 4, a nanodot memory fabrication method may include forming (or defining) an active area on a substrate 10. The active area may be formed of any semiconductor material appreciated in the art. A first insulating film 20 may be formed on a surface of the substrate 10 (S10). The first insulating film may be selected from the group including a silicone oxide thin film, silicon oxynitride (SiON) thin film, silicon nitride thin film, titanium (Ti) oxide thin film, tantalum (Ta) oxide thin film, aluminum (Al) oxide thin film or hafnium (Hf) oxide thin film and/or laminate thin film thereof.

As shown in FIG. 2, a metal nanodot colloid solution 30 may be applied on the first insulating film 20 (S20). A spin coating method commonly used in a semiconductor fabrication process may be used to apply the metal nanodot colloid solution 30. The metal nanodot colloid solution 30 may be sprayed (or deposited) onto the substrate 10. The substrate 10 may be continuously spun. The substrate 10 may be spun at approximately 5 seconds at 500 rpm, 20 seconds at 2000 rpm or 5 seconds at 500 rpm. The metal nanodot colloid solution 30 may be applied with a more uniform thickness on the substrate 10. The metal nanodot colloid solution 30 is a solution having metal nanodot particles of nano-scale size within a solvent. The metal nanodot colloid solution 30 used herein may be synthesized by any method well-known in the art.

The metal nanodot colloid solution 30 may include nanodot particles formed of at least one metal selected from the group including nickel, cobalt, iron, platinum, silver, palladium and alloys thereof. The nanodot particles may be dissolved into a nonpolar solvent (e.g., hexane or diphenylether) in order to facilitate mixing the nanodot particles in the metal nanodot colloid solution 30.

The metal nanodot colloid solution 30 may include a dispersant. The dispersant may be formed of at least one material selected from the group including oleic acid, trioctylamine and trioctylphosphine. Due to characteristics of the dispersant, the metal nanodot particles within the metal nanodot colloid solution 30 may be more uniformly distributed.

Referring to FIG. 3, the substrate, having the metal nanodot colloid solution 30 applied thereon, may be dried to remove (or evaporate) a solvent of the metal nanodot colloid solution 30 such that a layer of nanodot particles 31 may form on the first insulating layer 20 (S30). The solvent of the metal nanodot colloid solution 30 may be removed (or evaporated) while the substrate 10 is introduced into a vacuum atmosphere to prevent (or reduce) contamination of the substrate 10. The solvent may be removed by any method appreciated in the art.

The nanodot particles may form a monolayer structure by adjusting a concentration of the metal nanodot particles within the metal nanodot colloid solution 30. The concentration of the metal nanodot particles within the metal nanodot colloid solution 30 may be approximately 0.5 to 1.2 wt %.

Residue remaining on the surface of the substrate 10 may be removed (S40).

The residue may be removed by treating the surface of the substrate 10, having the nanodot particles formed thereon, with oxygen plasma. The residue may be removed by subjecting (or exposing) the surface of the substrate 10 to a heat treatment at 300° C. or above. Residue from the metal nanodot colloid solution 30 remaining on the first insulating film 20 may be removed to prevent (or reduce) contamination during fabrication of the nanodot memory.

An atomic concentration of carbons introduced into the nanodot memory may be maintained at about 2% or less by passing the nanodot memory through a residue removal process in order to prevent (or reduce) the introduction of contaminants to the nanodot memory.

Referring to FIG. 4, a second insulating film 40 may be formed over the first insulating film 20 having the nanodot particles exposed thereon (S50). The second insulating film may partially surround the nanodot particles 31. An upper electrode 50 may be formed on the second insulating film 40 (S60).

The second insulating film 40 maybe formed of the same material as the first insulating film 20. The second insulating film 40 may be formed using a low-pressure chemical vapor deposition (LPCVD) process in order to reduce leakage current. The LPCVD process may be performed at a temperature range of 400° C. to 500° C.

The upper electrode 50 may be formed of a conductive material having a large work function value, which has range from 4 eV to 7 eV. The conductive material may be at least one selected from the group including nickel, platinum, titanium nitride (TiN), aluminum and polysilicon. The conductive material may contain impurities.

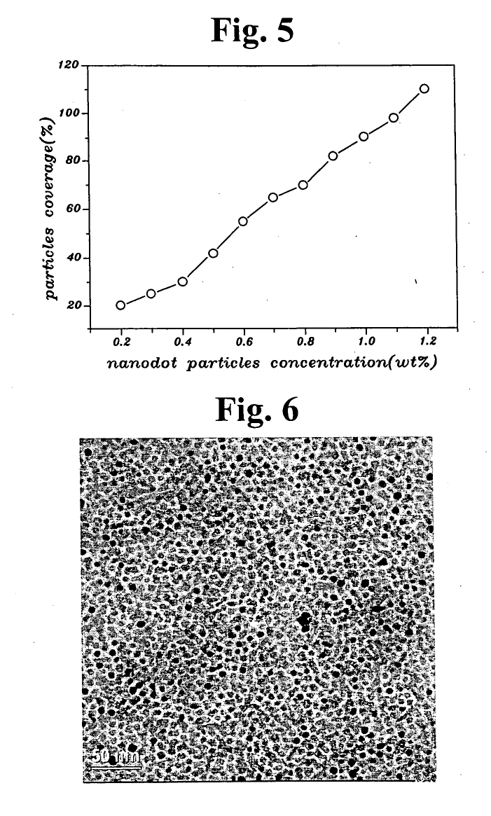

FIG. 5 is a graph showing particle coverage as a function of nanodot particle concentration in a metal nanodot solution fabricating by a nanodot memory fabrication method according to example embodiments of the present invention.

FIG. 6 is a TEM photograph of an arrangement of nanodot particles formed using a metal nanodot colloid solution including approximately 1.0 wt % nickel nanodot particles according to example embodiments of the present invention.

Referring to FIG. 5, the nanodot particle concentration may be measured using TEM (Transmission Electron Microscope) photography when nickel nanodot particles, which are used as metal in the metal nanodot solution, may be formed on a first insulating film.

Referring to FIGS. 5 and 6, when the metal nanodot particles concentration is about 1.2 wt %, approximately 90% of the second insulating film 40 (including the nanodot particles) may have a monolayer structure. As such, approximately 10% of the second insulating film 40 may not have nanodot particles. In other example embodiments, a multi-layer structure of nanodot particles may form.

A distance between the nanodot particles may be reduced to 5 nm if the nanodot particles concentration is greater than about 1.2 wt %. The distance between the nanodot particles may be adjusted by varying the molecular size of the dispersant. A ratio of the distance between the metal nanodot particles to the dispersant size may be about 2:1. For example, if the nanodot particles are about 10 nm apart, then the size of the dispersant maybe 5 nm.

By forming a layer of nanodot particles having the monolayer structure while controlling the distance between the nanodot particles, the nanodot memory may be formed such that the distance between the nanodot particles varies from about 1 nm to 10 nm.

When the nanodot particles concentration becomes less than about 0.5 wt %, an area ratio of the monolayer structure may be reduced to 50% or less. When the nanodot particles concentration is less than about 0.5 wt %, portions of the nanodot memory containing the nanodot particles may also decrease. An area of the nanodot memory covered by the nanodot particles having the monolayer structure may be adjusted by regulating the nanodot particles concentration in the metal nanodot colloid solution 30.

When the nanodot particles concentration in the metal nanodot colloid solution 30 is, for example, about 0.5 to 1.2 wt % based on the above-mentioned results, then the nanodot particles in the monolayer structure may be formed from the metal nanodot colloid solution 30 applied (or deposited) on the first insulating film 20.

Hereinafter, a nanodot memory fabricated by a nanodot memory fabrication method will be described. Example embodiments herein are described with reference to a nickel nanodot memory, however other nanodot memories are to be appreciated by those skilled in the art.

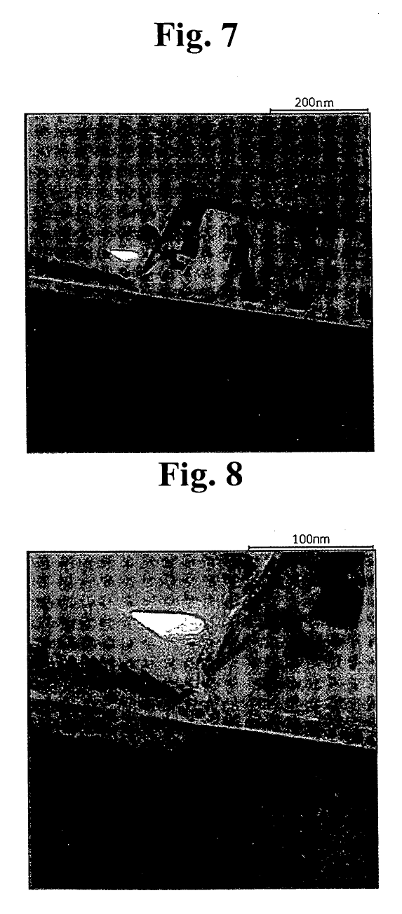

FIG. 7 is a sectional TEM photograph of a structure having a silicon oxide film, a nickel nanodot, a silicon oxide film and an aluminum electrode sequentially formed on a silicon substrate according to example embodiments of the present invention.

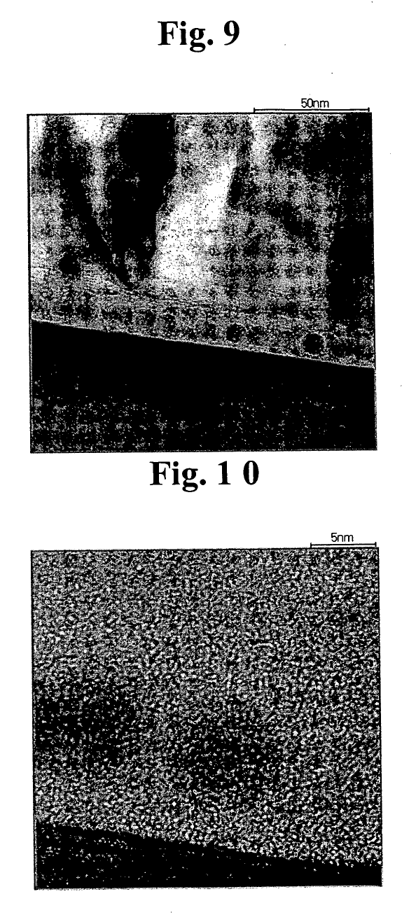

FIGS. 8 to 10 are magnified photographs of FIG. 7.

Referring to FIGS. 7 and 8, photographs taken by transmission electron microscopy show a silicon oxide film and nickel nanodot particles arranged in a monolayer structure. The size of the nickel nanodot particles is about 9 nm. The distance between the nickel nanodot particles is about 5 nm.

As shown in FIGS. 9 and 10, the nickel nanodot particles are more uniformly distributed within the insulating films. The effectiveness of the residue removal process in the nanodot memory fabrication method may be assessed by analyzing contamination resulting from carbon introduced into the nanodot memory.

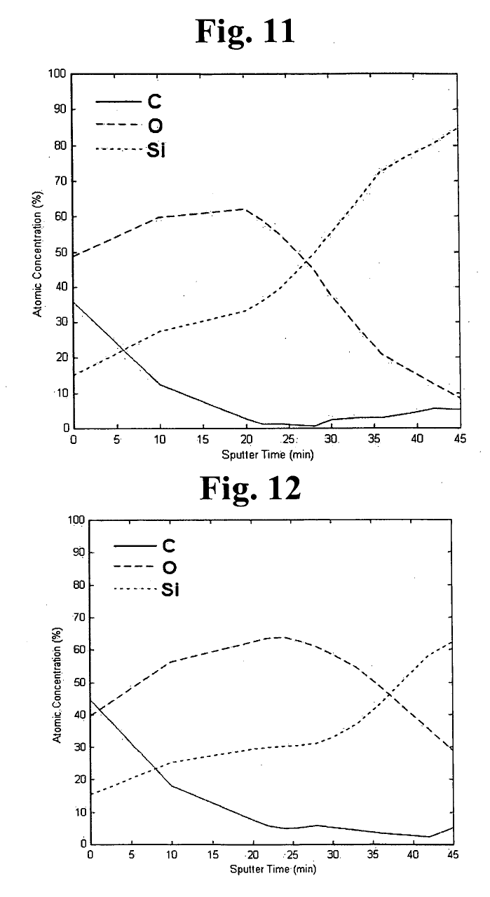

FIG. 11 is a graph showing the atomic concentration of carbon atoms implanted into a device that is treated with oxygen plasma as a function of sputter time according to example embodiments of the present invention.

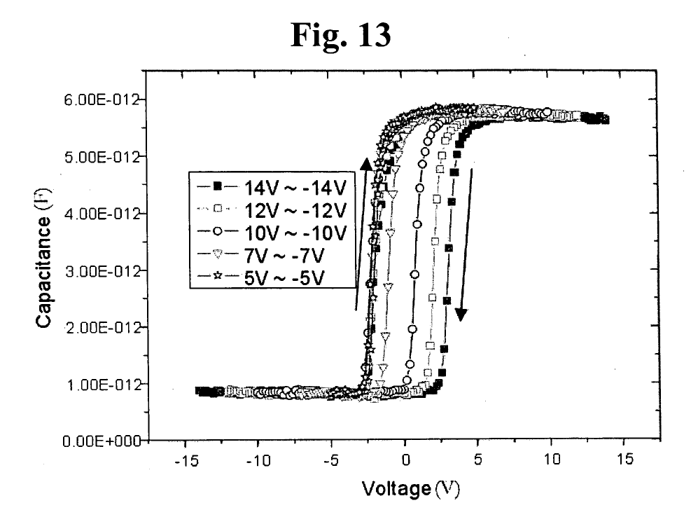

FIG. 12 is a graph showing atomic concentration of carbon atoms implanted into a device that is not treated with oxygen plasma as a function of sputter time according to example embodiments of the present invention.

The data shown in FIGS. 11 and 12 was collected by analyzing vertical cross-sections of the nanodot memory structure using secondary ion mass spectroscopy. The abscissa (or x-axis) of the graphs refers to a depth directional sputter time in minutes (min). The ordinate (or y-axis) of the graphs refers to an atomic concentration in percentage (%).

Along the abscissa, the sputter time of 0 to 20 minutes corresponds to a silicon oxide film area of the second insulating film. The sputter time of 20 to 35 minutes corresponds to a nickel nanodot area and a silicon oxide film area of the first insulating film. At a sputter time of 35 minutes, the silicon oxide film area may be converted into a silicon substrate area.

Comparing the results in FIGS. 11 and 12, the carbon atomic concentration in the nickel nanodot area and the first insulating film area may be reduced from approximately 4% or greater to approximately 2% or less when the residue is removed through the oxygen plasma treatment. A residue removal effect, having the same results, may be obtained when a heat treatment is performed at a temperature of about 300° C. or above.

Hereinafter, a nanodot memory in accordance with other example embodiments will be described with reference to FIGS. 4 and 7 to 10.

A nanodot memory fabricated by a nanodot memory fabrication method may include a substrate 10, a first insulating film 20, a plurality of nanodot gates 31, a second insulating film 40 and/or an upper electrode 50. The nanodot gates 31 may be formed using a metal nanodot colloid solution 30. A distance between the nanodot gates 31 may be about 5 nm or less. The nanodot gates 31 may be formed by nanodot particles.

The substrate 10 may be formed of semiconductor materials appreciated in the art (e.g., silicon and compounds thereof). The first insulating film 20 may be formed on the substrate 10. The nanodot gates 31, arranged on the first insulating film 20, may be a monolayer of nanodot particles. The monolayer of nanodot particles may be formed according to the nanodot memory fabrication method described above.

The second insulating film 40 may be formed on the first insulating film 20 and the metal nanodot gates 31. The upper electrode 50 may be formed on the second insulating film 40.

The first insulating film 20 and second insulating film 40 may be selected from the group including a silicone oxide thin film, silicon oxynitride thin film, silicon nitride thin film, titanium oxide thin film, aluminum oxide thin film, hafnium oxide thin film and/or laminate thin film thereof. The nanodot gates 31 may be formed of a material selected from the group including nickel, cobalt, iron, platinum, silver, palladium and alloys thereof.

FIG. 13 is a graph showing capacitance as a function of voltage hysteresis characteristic of a capacitor having the structure of FIG. 7.

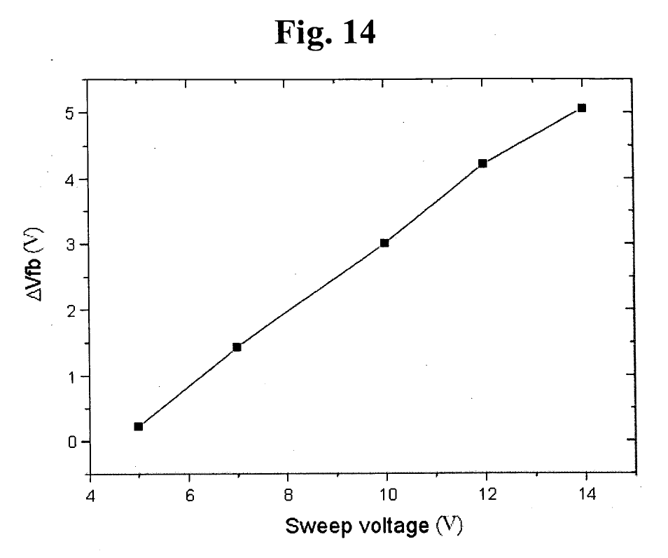

FIG. 14 is a graph showing flat band voltage characteristic as a function of maximum sweep voltage according to example embodiments of the present invention.

FIGS. 13 or 14 show the charge accumulation capability of a nanodot memory structure formed using an n-type silicon substrate. FIG. 14 shows the change in the flat band voltage (ΔVfb) as a function of the maximum sweep voltage derived using the data shown in FIG. 13.

As shown in FIGS. 13 and 14, the nanodot memory fabricated according to example embodiments of the present invention has electrical properties comparable with non-volatile memories used in the conventional art.

A nanodot memory having a nanodot structure may be more easily fabricated in such a manner that a metal nanodot colloid solution may be applied on a substrate by means of a spin coating method to form monolayer nanodot particles with a more uniform arrangement.

Nanodot particles for fabricating a nanodot memory may be more easily formed in a monolayer structure by adjusting a concentration of metal nanodot particles within a metal nanodot colloid solution.

Nanodot particles formed on a first insulating film may be treated with oxygen plasma, or may be subjected (or exposed) to a heat treatment such that organic contamination in a device area of a nanodot memory, particularly in a critical tunnel oxide portion, may be reduced.

The foregoing is illustrative of the example embodiments of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method for fabricating a nanodot memory, comprising:
forming a first insulating film on a surface of a substrate;
applying a nanodot colloid solution on the first insulating film;
removing a solvent in the nanodot colloid solution such that a plurality of nanodot particles layer remain exposed on the first insulating film;
forming a second insulating film on the nanodot particles; and
forming an upper electrode on the second insulating film,
wherein the nanodot particles are formed in a monolayer structure by adjusting a concentration of the nanodot particles in the nanodot colloid solution.

2. The method according to claim 1, wherein the concentration of the nanodot particles in the nanodot colloid solution is about 0.5 to 1.2 wt %.

3. The method according to claim 1, wherein the nanodot colloid solution is a metal nanodot colloid solution; and the nanodot particles are metal nanodot particles.

4. The method according to claim 3, wherein the metal nanodot colloid solution includes a metal selected from the group including nickel, cobalt, iron, platinum, silver, palladium and alloys thereof.

5. The method according to claim 1, wherein the solvent is a nonpolar solvent.

6. The method according to claim 5, wherein the nonpolar solvent is hexane or diphenylether.

7. The method according to claim 1, wherein the nanodot colloid solution includes a dispersant.

8. The method according to claim 7, wherein the dispersant includes at least one compound selected from the group including oleic acid, trioctylamine and trioctylphosphine.

9. The method according to claim 1, wherein the nanodot colloid solution is applied by a spin coating method.

10. The method according to claim 1, wherein the first insulating film and the second insulating film are each formed of at least one film selected from the group including a silicone oxide thin film, a silicon oxynitride thin film, a silicon nitride thin film, a titanium oxide thin film, an aluminum oxide thin film or a hafnium oxide thin film and a laminate thin film thereof.

11. The method according to claim 1, wherein forming the second insulating film includes performing a low-pressure chemical vapor deposition process.

12. The method according to claim 1, wherein removing the solvent includes evaporating the solvent under vacuum.

13. The method according to claim 1, further comprising:
treating the surface of the substrate with oxygen plasma after exposing the nanodot particles.

14. The method according to claim 1, further comprising:
subjecting the substrate to a heat treatment at a temperature of 300° C. or above after exposing the nanodot particles.

15. A nanodot memory comprising:
a substrate of semiconductor material;
a first insulating film on the substrate;
a plurality of nanodot gates remaining on the first insulating film from a nanodot colloid solution;
a second insulating film on the first insulating film and the nanodot gates; and
an upper electrode on the second insulating film.

16. The nanodot memory of claim 15, wherein the nanodot gates are a monolayer of nanodot particles.

17. The nanodot memory of claim 15, wherein a distance between the nanodot gates is approximately 1 nm to 10 nm.

18. The nanodot memory of claim 15, wherein the nanodot gates are formed of at least one metal selected from the group including nickel, cobalt, iron, platinum, silver, palladium and alloys thereof.

19. The nanodot memory of claim 15, wherein a carbon atomic concentration of the nanodot gates is about 2% or less.

20. The nanodot memory of claim 15, wherein the first insulating film and second insulating film are formed of at least film selected from the group including a silicone oxide thin film, a silicon oxynitride thin film, a silicon nitride thin film, a titanium oxide thin film, an aluminum oxide thin film or a hafnium oxide thin film and a laminate thin film thereof.
